(19) United States
(12) Patent Application Publication
(10) Pub. No.: US 2025/0199294 A1
(43) Pub. Date: Jun. 19, 2025

(54) METHOD TO ADJUST AN ILLUMINATION BEAM PATH WITHIN AN ILLUMINATION OPTICS AND ILLUMINATION OPTICS HAVING AN ADJUSTMENT SYSTEM

(71) Applicant: Carl Zeiss SMT GmbH, Oberkochen (DE)

(72) Inventors: Albertus HARTGERS, DR Veldhoven (NL); Marco Matheus Louis STEEGHS, DR Veldhoven (NL); Geert SWINKELS, DR Veldhoven (NL)

(21) Appl. No.: 19/073,366

(22) Filed: Mar. 7, 2025

Related U.S. Application Data
(63) Continuation of application No. PCT/EP2023/074892, filed on Sep. 11, 2023.

(30) Foreign Application Priority Data
Sep. 13, 2022 (DE) 10 2022 209 532.4

(51) Int. Cl. G02B 26/12; G02B 26/08

(52) U.S. Cl. CPC G02B 26/12; G02B 26/0816

(57) ABSTRACT

A method adjusts an illumination beam path within an illumination optics having a first facet mirror with a plurality of mirror facets being tiltable via respective actuators and further having a second facet mirror with a plurality of micro mirrors, each being equipped with a thermal load sensor. The micro mirrors are groupable in micro mirror groups, each of these being attributed to one of the plurality of mirror facets.

### CROSS-REFERENCE TO RELATED APPLICATIONS

The present application is a continuation of, and claims benefit under 35 USC 120 to, international application No. PCT/EP2023/074892, filed Sep. 11, 2023, which claims benefit under 35 USC 119 of German Application No. 10 2022 209 532.4, filed Sep. 13, 2022. The entire disclosure of each of these applications is incorporated by reference herein.

### FIELD

The disclosure relates to a method to adjust an illumination beam path within an illumination optics. Further, the disclosure relates to an illumination optics having an adjustment system, to an illumination system comprising such illumination optics, to a projection exposure apparatus comprising such illumination system, to a method to produce a structured component by use of such projection exposure apparatus to a structured component produced by such production method and to a computer software product to execute such adjustment method.

### BACKGROUND

A projection exposure apparatus including an illumination system having an illumination optics including components to be adjusted with respect to each other are known from e.g. WO 2022/043226 A1 and WO 2013/167409 A1. A calibration method is known from DE 10 2011 114 156 B3. DE 10 2015 219 447 A1 discloses a calibration method for a micro mirror array arrangement. DE 10 2011 076 460 A1 discloses an illumination optics for EUV microlithography.

### SUMMARY

The present disclosure seeks to develop a method to adjust an illumination beam path within an illumination optics having a first and a second facet mirror which gives the possibility of a reliable and/or a fast adjustment result.

In an aspect, the disclosure provides a method to adjust an illumination beam path within an illumination optics. The illumination optics comprise: a first facet mirror having a plurality of mirror facets which are tiltable via respective actuators; and a second facet mirror having a plurality of micro mirrors, each being equipped with a thermal load sensor, the micro mirrors being groupable in micro mirror groups, each of these micro mirror groups being attributed to one of the plurality of mirror facets of the first facet mirror via a given illumination channel within the illumination beam path. The method includes guiding illumination light along a first raw illumination beam path via: at least one illuminated mirror facet of the field facet mirror; and the micro mirrors of the second facet mirror to which the illumination light is guided via the at least one illuminated mirror facet of the field facet mirror. The method also includes measuring a thermal load on the illuminated micro mirrors of the second facet mirror, and comparing the measured thermal load to nominal data. The method further includes, in case a deviation between the measured thermal load and the nominal data is beyond a given tolerance, readjusting the illumination optics.

In a given illumination beam path, all micro mirrors of the micro mirror group being attributed to one of the mirror facets of the first facet mirror via the given illumination channel can be illuminated in parallel, i.e. simultaneously, with the illumination beam.

It has been recognized by the inventors that micro mirrors of the second facet mirror of the illumination optics being equipped with a thermal load sensor are helpful to measure an actual alignment status of the illumination beam path impinging upon the micro mirrors of such second facet mirror. Measurement data of the thermal load sensors can be used as inputs for an illumination optics readjustment step of the method. An alignment of illumination channel guided within the illumination beam path via the two facet mirrors can be supervised, for example adjusted. A calibration of the mirror facets of the first facet mirror and/or the micro mirrors of the second facet mirror can be realized. Further, a homogeneity of a thermal load on the respective facet mirror and/or a homogeneity of an illumination of the respective facet mirror and/or a homogeneity of a residual absorption of the mirror facets or the micro mirrors of the respective facet mirror can be checked, corrected and/or compensated during the method. As a result, an undesired thermal overload of the micro mirrors can be avoided. The second facet mirror can be embodied as an MEMS (Micro Electro Mechanical System) mirror. Such mirrors are known from the above mentioned references and further are known e.g. from DE 10 2008 009 690 A1. Readjustment of the illumination optics may be done via the actuators of the mirror facets of the first facet mirror. Further, such readjustment of the illumination optics may be done via control of other adjustment actuators of the illumination optics. With such readjustment, a more homogeneous thermal load on the micro mirrors of the second facet mirror may be achieved. Further, an unwanted clipping of illumination light at the borders of the respective micro mirror group can be avoided.

The adjustment system may be embodied as a calibration system.

The method can further include: determining an actual value of a position of a center of gravity of the thermal load for a respective group of the illuminated micro mirrors of the second facet mirror using thermal load measurement data obtained during the measuring step; comparing such actual value with a nominal value of the position of the center of gravity of the thermal load; and, in case a distance between the actual value and the nominal value is beyond a given tolerance value for a given attributed micro mirror group, readjusting via the respective actuator the illuminated mirror facet of the field facet mirror until such distance is below the tolerance value. In such embodiments, beam paths of respective illumination channels can be aligned on the second facet mirror. This beam path alignment is possible as an initial alignment during the setup of the illumination optics or can be part of a readjustment/calibration process. If large tilt errors of the mirror facets and/or the micro mirrors of the illumination optics to be checked are to be expected, such method may be done offline, i.e. not during production time spans. The group of micro mirrors of the second facet mirror for which the actual value of the position of the center of gravity of the thermal load is determined, can be any group of interest.

In some embodiments, the mirror facets of the field facet mirror each include a plurality of micro mirrors each being equipped with a thermal load sensor and the method includes the step of measuring a thermal load on the illuminated micro mirrors of the first facet mirror. Such embodiments can expand the capability of micro mirrors equipped with thermal load sensors to the field facet mirror. Such field facet mirror also may be realized as a MEMS mirror. The mirror facets of such first facet mirror may be realized as virtual facets. In that respect, it is also referred to the publications mentioned above, in particular to DE 10 2008 009 690 A1. Again, Homogeneity/inhomogeneity measurements and respective alignment remedies of unwanted thermal loads or of unwanted clipping of illumination light at the borders of the respective mirror facet can be performed as discussed above with respect to the second facet mirror.

In some embodiments, the method further includes: guiding the illumination light along the first raw illumination beam path via at least one illuminated mirror facet of the field facet mirror and the attributed micro mirror group of the second facet mirror to which the illumination light is guided via the at least one illuminated mirror facet of the field facet mirror; measuring the thermal load on the respectively attributed micro mirror groups; determining for each of the attributed micro mirror groups an actual value of the position of the center of gravity of the thermal load; comparing for each of the attributed micro mirror groups such actual value with a nominal value of the position of the center of gravity of the thermal load; and, in case a distance between the actual value and the nominal value is beyond a given tolerance value for a given attributed micro mirror group, readjusting via the respective actuator the illuminated mirror facet of the field facet mirror to which the attributed micro mirror group belongs until such distance is below the tolerance value. In such embodiments, an alignment between mirror parts of the first and the second facet mirror attributed to each other via respective channels of the illumination light path can be checked and, if desired, readjusted. For example, in case the second facet mirror is embodied as a pupil facet mirror, the quality of an imaging of a light source onto the respective micro mirror group of the second facet mirror can be checked and, if desired, corrected. Such quality of the source imaging can be improved via respective actuation of the mirror parts of the first facet mirror.

The attributed micro mirror group can include a micro mirror array of at least 2×2 micro mirrors. Such a micro mirror array is an example for an attributed micro mirror group of the second facet mirror. Such micro mirror array also may be embodied as a 3×3, 4×4, 5×5, 6×6, 7×7 array or even arrays with a larger amount of mirrors, e.g. a 10×10 array. Also, arrays with different numbers of micro mirrors in the two dimensions are possible, i.e. a 7×10 micro mirror array.

The micro mirrors may have a rectangular reflection surface. Variants of such micro mirrors may have a circular, an elliptic, or a polygonal, e.g. hexagonal, reflection surface. In case of a rectangular reflection surface, this may be a square or may have different edge lengths. An aspect ratio of such edge lengths along coordinates perpendicular to each other may be in the range between 1.0 and 5, such as in the range between 1.1. and 2.

The measurement step can take place during production use of the illumination optics within a protection exposure apparatus. An in-line use of such a method during the production use does not require downtime.

Groups of micro mirrors can be used during the measurement which are not used for production use. With such methods, execution of the adjustment method is possible without affecting the production process. A readjustment is possible also for mirror facets which are not illuminated during the adjustment by using an offset and/or calibration information obtained for those mirrors illuminated during the adjustment. Here, drift effects, which may occur for all mirror parts of the facet mirrors the same way can be compensated for. This can be also used for calibration purposes.

In some embodiments, the steps guiding, measuring, and determining are done for a plurality of illuminated mirror facets of the first facet mirror and respectively attributed micro mirror groups of the second facet mirror and the respectively determined actual values of the position of the center of gravity of the thermal load are stored for each pair including the respective illuminated mirror facets of the field facet mirror and the attributed micro mirror group of the second facet mirror. An analysis of data gathered with such a method can be performed on those stored actual values including further data, e.g. source data, e.g. plasma alignment data in the case of a plasma source. Here, by including those further data, a deeper insight into the performance of the illumination system and also of the projection exposure apparatus equipped with such illumination system is possible enabling, in particular, a more sophisticated adjustment and/or maintenance.

In an aspect, the disclosure provides an illumination optics having an adjustment system comprising: a first facet mirror having a plurality of mirror facets which are tiltable via respective actuators; a second facet mirror having a plurality of micro mirrors, each being equipped with a thermal load sensor, the micro mirrors being groupable in micro mirror groups, each of these micro mirror groups being attributed to one of the plurality of mirror facets of the first facet mirror via a given illumination channel within an illumination beam path; and a control unit in signal connection with the actuators of the mirror facets of the field facet mirror and with the thermal load sensors of the micro mirrors of the second facet mirror.

Features of such an illumination optics correspond to those which already have been discussed with respect to the adjustment method above. The control unit can perform, for example, the comparing and the readjustment step of the method. If applicable, also the determining step can be performed by the control unit.

In some embodiments of an illumination optics, the mirror facets of the field facet mirror each include a plurality of micro mirrors, each being equipped with a thermal load sensor. Features of such an illumination optics correspond to some of those mentioned above.

In some embodiments, the disclosure provides an illumination system can include an illumination optics and a light source. In some embodiments, the disclosure provides a projection exposure system can include such an illumination optics. In some embodiments, the disclosure provides a method can include using such a projection exposure system to make a structured component. In some embodiments, the disclosure provide such a structure component. In some embodiments, the disclosure provides a software program product, stored on a computer storage medium comprising a computer readable software mechanism which can execute method steps disclosed herein. Features of such embodiments correspond to those discussed above with respect to the method and with respect to the illumination optics.

A microstructured or nanostructured component produced by a method may be a semiconductor chip, in particular, a memory chip.

At least one exemplary embodiment of the disclosure is described below on the basis of the drawings.

### BRIEF DESCRIPTION OF THE DRAWINGS

In the drawings:

FIG. 1 schematically shows a meridional section of a projection exposure apparatus for EUV projection lithography, including an illumination system comprising an illumination light source and an illumination optics having an adjustment system;

FIG. 2 a further embodiment of an illumination system which also can be used in the projection exposure apparatus of FIG. 1;

FIG. 3 a plan view of an arrangement of mirror facets of a first facet mirror of the illumination optics, each mirror facet including a plurality of micro mirrors;

FIG. 4 also in a plan view, an arrangement of a plurality of micro mirrors being part of a second facet mirror of the illumination optics; and

FIG. 5 a cross section through a row of the micro mirrors of the arrangement of FIG. 3 along direction V in FIG. 4.

### DETAILED DESCRIPTION

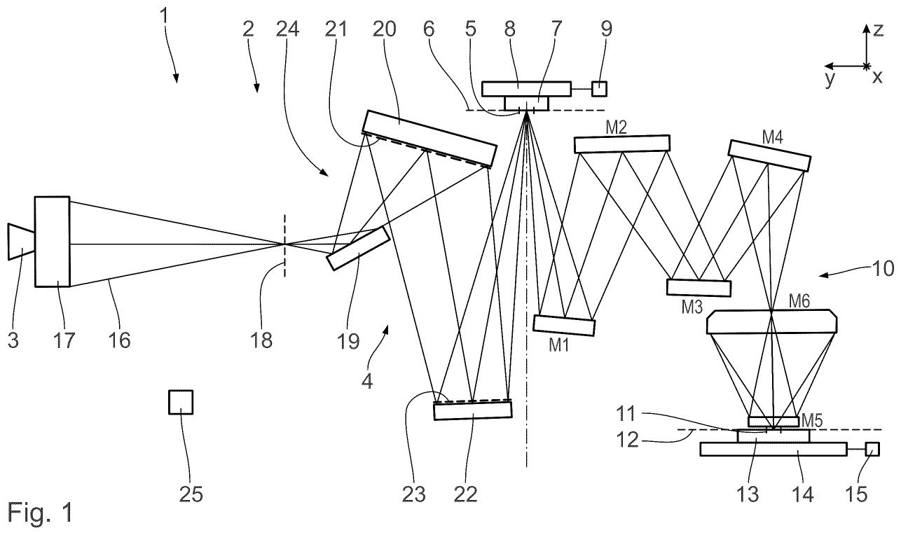

In the following text, certain components of a microlithographic projection exposure apparatus 1 are described first by way of example with reference to FIG. 1. The description of the basic construction of the projection exposure apparatus 1 and its components should not be construed as limiting here.

An illumination system 2 of the projection exposure apparatus 1 has, besides a radiation or light source 3, an illumination optical unit 4 also referred to as an illumination optics for illuminating an object field 5 in an object plane 6. In this case, a reticle 7 arranged in the object field 5 is exposed. The reticle 7 is held by a reticle holder 8. The reticle holder 8 is displaceable by way of a reticle displacement drive 9, in particular in a scanning direction.

A global Cartesian xyz-coordinate system is shown in FIG. 1 for explanation purposes. The x-direction extends perpendicular to the plane of the drawing. The y-direction extends horizontally, and the z-direction extends vertically. The scanning direction extends along the y-direction in FIG. 1. The z-direction extends perpendicular to the object plane 6.

In the subsequent figures, a local xy- or xyz-coordinate system is optionally used for elucidation purposes. The x-direction of the respective local coordinate system corresponds to that of the global coordinate system. The y- and the z-direction of the local coordinate system are tilted about this common x-direction depending on an orientation of the component to be described.

The projection exposure apparatus 1 comprises a projection optical unit 10 which also is referred to as a projection optics. The projection optical unit 10 serves for imaging the object field 5 into an image field 11 in an image plane 12. The image plane 12 extends parallel to the object plane 6. Alternatively, an angle between the object plane 6 and the image plane 12 that differs from 0° is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable in particular along the y-direction via a wafer displacement drive 15. The displacement, firstly, of the reticle 7 by way of the reticle displacement drive 9 and, secondly, of the wafer 13 by way of the wafer displacement drive 15 can be implemented so as to be synchronized to one another.

The radiation source 3 is an EUV radiation source. The radiation source 3 emits, in particular, EUV radiation 16, which is also referred to below as used radiation or illumination radiation. In particular, the used radiation has a wavelength in the range between 5 nm and 30 nm. The radiation source 3 can be a plasma source, for example an LPP (laser produced plasma) or GDPP (gas discharge produced plasma) source. It can also be a synchrotron-based radiation source. The radiation source 3 can be a free electron laser (FEL).

The illumination radiation 16 emerging from the radiation source 3 is focused by a collector 17. The collector 17 can be a collector with one or with a plurality of ellipsoidal and/or hyperboloid reflection surfaces. The at least one reflection surface of the collector 17 can be impinged upon by illumination radiation 16 with grazing incidence (GI), i.e., at angles of incidence of greater than 45°, or with normal incidence (NI), i.e., at angles of incidence of less than 45°. The collector 17 can be structured and/or coated, firstly, for optimizing its reflectivity for the used radiation and, secondly, for suppressing extraneous light.

The illumination radiation 16 propagates through an intermediate focus in an intermediate focal plane 18 downstream of the collector 17. The intermediate focal plane 18 can represent a separation between a radiation source module, having the radiation source 3 and the collector 17, and the illumination optical unit 4.

The illumination optical unit 4 comprises a deflection mirror 19 and, arranged downstream thereof in the beam path, a first facet mirror 20. The deflection mirror 19 can be a plane deflection mirror or, alternatively, a mirror with a beam-influencing effect going beyond a pure deflection effect. As an alternative or in addition thereto, the mirror 19 can be embodied as a spectral filter separating a used wavelength of the illumination radiation 16 from extraneous light having a wavelength that deviates therefrom. If the first facet mirror 20 is arranged in a plane of the illumination optical unit 4 that is optically conjugate to the object plane 6 as a field plane, the facet mirror is also referred to as a field facet mirror. The first facet mirror 20 comprises a multiplicity of individual first facets 21, which are also referred to as field facets or mirror facets below. Some of these facets 21 are shown in FIG. 1 only by way of example.

The first facets 21 can be embodied as macroscopic facets, in particular as rectangular facets or as facets with an arcuate edge contour or an edge contour of part of a circle. The first facets 21 can be embodied as plane facets or, alternatively, as convexly or concavely curved facets.

As is known e.g. from WO 2022/043226 A1, WO 2013/167409 A1, or from DE 10 2008 009 600 A1, for example, the first facets 21 themselves can also each be composed of a multiplicity of individual mirrors, in particular a multiplicity of micro mirrors which will be explained in more detail hereinafter. The first facet mirror 20 can in particular be designed as a microelectromechanical system (MEMS system).

In the embodiment according to FIG. 1, the illumination radiation 16 travels horizontally, i.e., along the y-direction, between the collector 17 and the deflection mirror 19.

In the beam path of the illumination optical unit 4, a second facet mirror 22 is arranged downstream of the first facet mirror 20. If the second facet mirror 22 is arranged in or in the vicinity of a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known e.g. from US 2006/0132747 A1, EP 1 614 008 B1 and U.S. Pat. No. 6,573,978.

The first facet mirror 20 and/or the second facet mirror 22 may have an extension in the xy-plane in the range of 1 m×1 m.

The second facet mirror 22 comprises a plurality of second facets 23. In the case of a pupil facet mirror, the second facets 23 are also referred to as pupil facets.

The second facets 23 are facets composed of micro mirrors, which also is explained in more detail hereinafter. In this regard, reference is also made to DE 10 2008 009 600 A1.

The second facets 23 can have plane or, alternatively, convexly or concavely curved reflection surfaces.

The illumination optical unit 4 consequently forms a double-faceted system. This basic principle is also referred to as a fly's eye integrator or honeycomb condenser.

It can be advantageous to arrange the second facet mirror 22 not exactly within a plane that is optically conjugate to a pupil plane of the projection optical unit 7.

The individual first facets 21 are imaged into the object field 5 with the aid of the second facet mirror 22. The second facet mirror 22 is the last beam-shaping mirror or, in fact, the last mirror for the illumination radiation 16 in the beam path upstream of the object field 5.

In a further embodiment of the illumination optical unit 4 (not illustrated), a transmission optical unit contributing in particular to the imaging of the first facets 21 into the object field 5 can be arranged in the beam path between the second facet mirror 22 and the object field 5. The transmission optical unit can have exactly one mirror or, alternatively, two or more mirrors, which are arranged in succession in the beam path of the illumination optical unit 4. The transmission optical unit can in particular comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the field facet mirror 20 and the pupil facet mirror 22.

The deflection mirror 19 can also be dispensed with in a further embodiment of the illumination optical unit 4, and the illumination optical unit 4 can then have exactly two mirrors downstream of the collector 17, specifically the first facet mirror 20 and the second facet mirror 22.

As a rule, the imaging of the first facets 21 into the object plane 6 via the second facets 23 or using the second facets 23 and a transmission optical unit is only approximate imaging.

Part of the illumination optics 4 is an adjustment or calibration system 24 to adjust or calibrate the mirror facets 21 of the first facet mirror 20 and/or to adjust or calibrate the micro mirrors of the second facet mirror 22. Details of such adjustment system 24 are explained later. Part of this adjustment system 24 is a control unit 25 schematically depicted in FIG. 1.

The projection optical unit 10 comprises a plurality of mirrors Mi, which are numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or any other number of mirrors Mi are likewise possible. The penultimate mirror M5 and the last mirror M6 each have a through opening for the illumination radiation 16. The projection optical unit 10 is a double-obscured optical unit. The projection optical unit 10 has an image-side numerical aperture that is greater than 0.5 and can also be greater than 0.6 and, for example, be 0.7 or 0.75.

Reflection surfaces of the mirrors Mi can be embodied as free-form surfaces without an axis of rotational symmetry. Alternatively, the reflection surfaces of the mirrors Mi can be designed as aspherical surfaces with exactly one axis of rotational symmetry of the reflection surface form. Just like the mirrors of the illumination optical unit 4, the mirrors Mi can have highly reflective coatings for the illumination radiation 16. These coatings can be designed as multilayer coatings, in particular with alternating layers of molybdenum and silicon.

The projection optical unit 10 has a large object-image offset in the y-direction between a y-coordinate of a centre of the object field 5 and a y-coordinate of the centre of the image field 11. In the y-direction, the object-image offset can be approximately the same size as a z-distance between the object plane 6 and the image plane 12.

In particular, the projection optical unit 10 can have an anamorphic design. In particular, it has different imaging scales βₓ, β_{y} in the x- and y-directions. The two imaging scales βₓ, β_{y} of the projection optical unit 7 can lie at (βₓ, β_{y})=(+/−0.25, +/−0.125). A positive imaging scale β means imaging without image erection. A negative sign for the imaging scale β means imaging with image erection.

Consequently, the projection optical unit 7 leads to a reduction with a ratio of 4:1 in the x-direction, i.e., in a direction perpendicular to the scanning direction.

The projection optical unit 10 leads to a reduction of 8:1 in the y-direction, i.e., in the scanning direction.

Other imaging scales are likewise possible. Imaging scales with the same sign and the same absolute value in the x- and y-directions are also possible, for example with absolute values of 0.125 or 0.25.

The number of intermediate image planes in the x- and in the y-direction in the beam path between the object field 5 and the image field 11 can be the same or, depending on the embodiment of the projection optical unit 10, can be different. Examples of projection optical units with different numbers of such intermediate images in the x- and y-directions are known from US 2018/0074303 A1.

In each case one of the pupil facets 23 is assigned to exactly one of the field facets 21 for forming in each case an illumination channel for illuminating the object field 5. In particular, this can produce illumination according to the Köhler principle. An illumination region of an arrangement plane of the field facets 21, which is also referred to as the far field, is decomposed into a multiplicity of object fields 5 with the aid of the field facets 21. The field facets 21 produce a plurality of images of the intermediate focus on the pupil facets 23 respectively assigned thereto.

The field facets 21 are imaged, in each case by way of an assigned pupil facet 23, onto the reticle 7 in a manner such that they are overlaid on one another for the purposes of illuminating the object field 5. The illumination of the object field 5 is in particular as homogeneous as possible. It can have a uniformity error of less than 2%. Field uniformity can be attained by overlaying different illumination channels.

The illumination of the entrance pupil of the projection optical unit 10 can be geometrically defined by an arrangement of the pupil facets. The intensity distribution in the entrance pupil of the projection optical unit 10 can be set by selecting the illumination channels, in particular the subset of pupil facets, which guide light. This intensity distribution is also referred to as illumination setting.

A likewise preferred pupil uniformity in the region of sections of an illumination pupil of the illumination optical unit 4 that are illuminated in a defined manner can be achieved by a redistribution of the illumination channels.

Further aspects and details of the illumination of the object field 5 and, in particular, of the entrance pupil of the projection optical unit 10 are described below.

In particular, the projection optical unit 10 can comprise a homocentric entrance pupil. The latter can be accessible. It can also be inaccessible.

The entrance pupil of the projection optical unit 10 cannot be illuminated regularly with the pupil facet mirror 22 in an exact manner. In the case of imaging the projection optical unit 10 in which the centre of the pupil facet mirror 22 is telecentrically imaged onto the wafer 13, the aperture rays often do not intersect at a single point. However, it is possible to find a surface in which the spacing of the aperture rays, determined in pairwise fashion, is minimal. This area represents the entrance pupil or an area in real space that is conjugate thereto. In particular, this area has a finite curvature.

The projection optical unit 10 might have different positions of the entrance pupil for the tangential beam path and for the sagittal beam path. In this case, an imaging element, in particular an optical component of the transmission optical unit, should be provided between the second facet mirror 22 and the reticle 7. With the aid of the optical element, the different positions of the tangential entrance pupil and the sagittal entrance pupil can be taken into account.

In the arrangement of the components of the illumination optical unit 4 illustrated in FIG. 1, the pupil facet mirror 22 is arranged in a surface conjugate to the entrance pupil of the projection optical unit 10. The field facet mirror 20 is arranged so as to be tilted with respect to the object plane 5. The first facet mirror 20 is arranged so as to be tilted with respect to an arrangement plane defined by the deflection mirror 19.

The first facet mirror 20 is arranged so as to be tilted with respect to an arrangement plane defined by the second facet mirror 22.

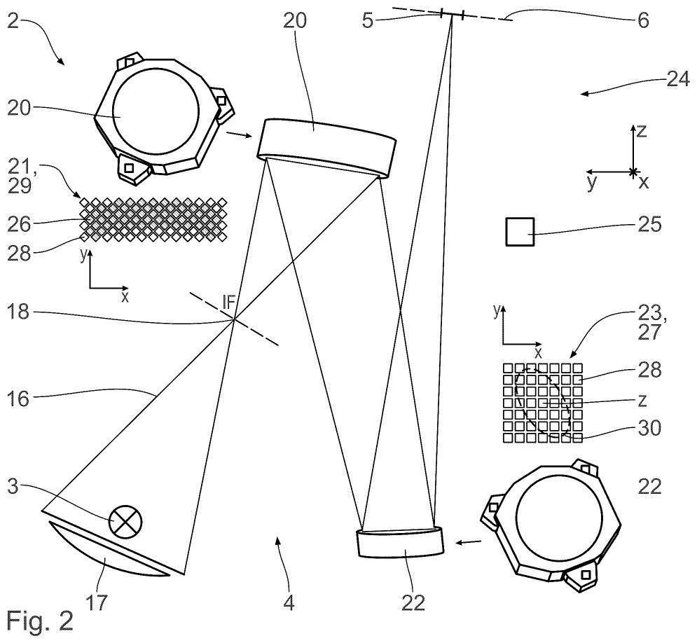

FIG. 2 shows a further embodiment of the illumination system 2 components and functions which correspond to those already discussed above with respect to FIG. 1 which are denoted with the same terms and reference numerals and are not discussed in detail again.

In FIG. 2, exemplary perspective views of the first facet mirror 20 and of the second facet mirror 22 also are depicted. Further, in the vicinity of these perspective views of the first facet mirror 20 on the one hand, and of the second facet mirror 22 on the other, micro mirror sub-arrangements 26, 27, i.e. respective micro mirror groups, are shown.

The micro mirror sub-arrangement 26 is an array of approximately 5×20 micro mirrors 28 of the first facet mirror 20. Highlighted via a hatching within the micro mirror sub-group 26 are those micro mirrors 28 which are grouped into a micro mirror group 29, constituting one of the mirror facets 21 of the first facet mirror 20. Such micro mirror group 29 also is denoted as a virtual facet or as a virtual field facet of the first mirror 20.

An xy-width of the respective micro mirror 28 may be in the range between 100 μm to 5 mm, in particular, between 500 μm to 2 mm.

The micro mirrors 28 of the first facet mirror 20 each are equipped with a thermal load sensor. Such thermal load sensors of the micro mirrors 28 are not depicted in FIG. 2. During impingement of the virtual field facets 21 of the first facet mirror 20, those micro mirrors 28 belonging to the micro mirror group 29 are impinged by the illumination light, i.e. the EUV-radiation 16. As a result of such impingement, the micro mirrors 28 of the micro mirror group 29 heat up due to residual absorption.

A thermal time-constant of a thermalisation of the individual micro mirrors 28 during impingement with the illumination light 16 may be less than 5 s and in particular may be less than 1 s. As a rule, such thermal time-constant is larger than 0.05 s.

The micro mirror sub-arrangement 27 of the second facet mirror 22, also shown in FIG. 2, is a micro mirror group representing one of the second facets or pupil facets 23 on the second facet mirror 22. Such micro mirror group 27 is embodied as a 7×7 array of micro mirrors 28. FIG. 2 shows that second facet 23, which is attributed to the shown virtual field facet 21 of the first facet mirror 20 via an illumination channel within an illumination beam path of the illumination light 16. In that sense, the respective micro mirror group 27 of the second facet mirror 22 is attributed to the respective mirror facet 21 of the first facet mirror 20 via the illumination beam path. Such attribution of an illuminated mirror facet 21 of the first facet mirror 20 and of the illuminated micro mirror group 27 of the second facet mirror 22 illuminated via the respective illumination light channel also is referred to as an attributed pair.

The micro mirrors 28 of the second facet mirror 22 also are equipped with thermal load sensors, which are not depicted in FIG. 2. The depiction of the micro mirror group 27, i.e. the second facet 23 in FIG. 2 shows a measured thermal load via the thermal load sensors of those micro mirrors 28 during impingement of the second facet 23 via the first facet 21 with the illumination light 16. Due to such impingement, in an aligned state of the illumination beam path, a contour of a source image 30 present at the center of the second facet 23 can be measured via the thermal load sensors. A center of gravity Z of the resulting thermal load is at the position of a central micro mirror 28 of the micro mirror group 27.

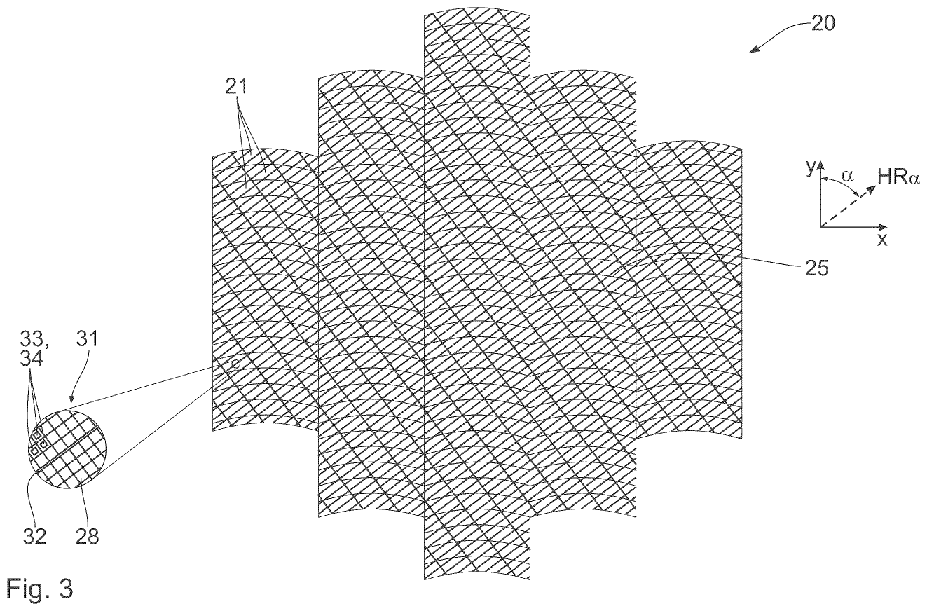

FIG. 3 shows an embodiment of an arrangement of the mirror facets 21 of the first facet mirror 20. Shown is an arrangement of tightly packed arcuate feed facets 21 which are arranged in five columns. With respect to details of such arrangement, it is referred WO 2013/167409 A1.

Enlarged, on the lower left corner of FIG. 3, is a micro mirror sub-group 31, which is part of one of the mirror facets 21. Such micro mirror sub-group 31 includes micro mirrors 28 of two adjacent micro mirror arrays of a MEMS mirror device constituting the first facet mirror 20, these two micro mirror arrays being divided by a gap 32. Such gap extends along a main direction HR_{α} having an angle of e.g. 37° to the y-coordinate. For more details, it is referred to WO 2013/167409 A1 and to WO 2009/100856 A1.

The mirror facets 21, i.e. the micro mirrors 28 belonging to the respective mirror facet 21, are tiltable via respective actuators 33, some of which being schematically depicted in FIG. 3. Those actuators 33 each also are equipped with a thermal load sensor 34. Each of the thermal load sensor 34 is capable to continuously measure a thermal load deposited on the respective micro mirror 28. As an alternative to a continuous measurement also measurement of a certain number of thermal load increments is possible, i.e. 2 to 50 or 2 to 10 of such thermal load increments.

Via these actuators 33, the micro mirrors 28 can be tilted individually or groupwise within one of the micro mirror groups 29 between at least two tilting positions.

The actuators 33 and the respective thermal loads sensors 34 are in signal connection with the control unit 25 of the adjustment system 24.

The actuators 33 may be embodied as piezo actuators.

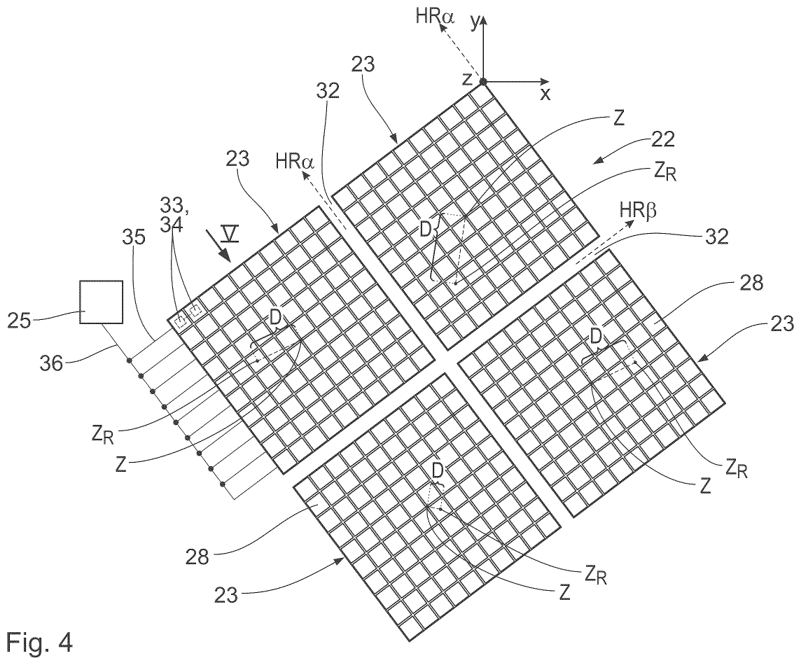

FIG. 4 shows an arrangement of four second facets 23, which are part of a MEMS device constituting the second facet mirror 22. Of course, the whole second facet mirror 22 includes a larger number of such second facets 23, which at least equals the number of mirror facets 21 of the first facet mirror 20, and in practice equals a number, which is at least two to five times as large as the number of mirror facets 21.

The second facets 23 are constituted in the FIG. 4 embodiment by arrays of 10×10 micro mirrors 28.

The MEMS devices constituting the first facet mirror 20 and the second facet mirror 22 are in principle of equal design.

In FIG. 4, also the gaps 32 between the respective mirror arrays, i.e. the second facets 23, are shown. Those gaps 32 extend in main direction HR_{α} with an angle of 37° to the y-coordinate and HR_{β} perpendicular to HR_{α}.

The micro mirrors 28 of the second facet 23, again, are equipped with actuators 33 and also with thermal load sensors 34. FIG. 4 also schematically depicts a wiring between those actuators 33 and thermal load sensors 34 to the control unit 25 via individual row lines 35 and a main line 36.

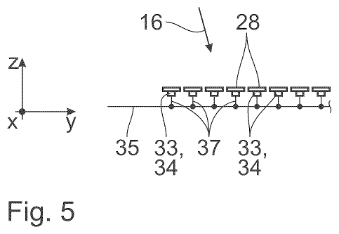

FIG. 5 illustrates such wiring within one row of the micro mirrors 28, which may be part of the MEMS device constituting the first facet mirror 20 or the second facet mirror 22. Each actuator 33 and thermal load sensor 34 is connected to the row line 35 via an individual line 37 for signal connection to the control unit 25.

Also shown in FIG. 5 is an exemplary ray of the illumination light 16 impinging on the micro mirrors 28.

During the setup of the illumination system 2, an illumination beam path within the illumination optics 4 is adjusted using the adjustment system 24 by carrying out an adjustment method. This also can be referred to as a calibration of the components of the illumination optics 4. Further, during the lifetime of the projection exposure apparatus 1, from time to time a readjustment and/or a recalibration using such method can be done.

During such method, the illumination light 16 initially is guided along a first raw illumination beam path via at least one or via several or via all of the mirror facets 21 of the first facet mirror 20 and further the micro mirrors 28 of the second facet mirror 22 to which the illumination light 16 is guided via the at least one illuminated mirror facet 21 of the first facet mirror 20. Within such raw illumination beam path, a correct attribution of the second facets 23 to the first mirror facets 21 may be given or, alternatively, may be not given.

Now, a thermal load on the illuminated micro mirrors 28 of the second facet mirror 22 is measured. With this measurement, actual positions of raw source images 30 of the light source 3 on the second facet mirror 22 can be detected. Due to the initial raw illumination beam path, the actual positions of the raw source images 30, may be offset from the nominal, centered positions. In FIG. 4, an example is given using a raw illumination beam path having an initial correct attribution of the second facets 23 to the first mirror facets 21 via the respective illumination channels of the raw illumination beam path. Here, the initially measured actual values Z_{R} of the positions of the centers of gravity of the thermal load caused by the respective source image 30 are depicted. As expected, all these actual values Z_{R} are offset from the nominal, centered positions Z of the centers of the respective second facets 23. The measured actual values Z_{R} are the thermal load centers of gravity of respectively decentered source images 30 (compare also FIG. 2).

After such thermal load measurement which is done via the thermal load sensors 34 of the respective micro mirrors 28 of the second facets 23 of the second facet mirror 22, via the control unit 25, a comparison between the measured thermal load to nominal data with respect to the nominal positions of the respective thermal load is performed. In the first instance, such nominal data includes that nominally the center of gravity of the respective thermal load caused by the respective source image 30 should be located at the center Z of the respective second facet 23. In more detail, the nominal data also can include data referring to a size or width of the source image 30, in particular to a nominal diameter and/or a nominal contour and/or, in case of an elongated source image 30, a nominal extension of the source image 30.

After the comparison between the measured thermal load and the nominal data has been performed, a deviation between the measured actual data and the nominal data is evaluated. In case such deviation, e.g. the distance between the actual center Z_{R} and the center Z, is beyond a given tolerance value, a readjustment is performed. Such tolerance value may be, in the case of a 10×10 array second facet 23 according to FIG. 4, a width of one of the micro mirrors 28 or 1.5 or 2 times the width of such micro mirror 28.

Such distance is depicted and denoted as D in FIG. 4.

In consequence, in the situation shown with the lower second facet 23 of FIG. 4, where a distance between the actual value Z_{R} of the position of the center of gravity of the thermal load and the nominal center Z of the respective second facet 23 is below the width of one of the micro mirrors 28, no readjustment needs to take place. In other cases, the readjustment includes a tilting of the micro mirrors 28 of the attributed micro mirror group 29, i.e. the mirror facet 21 of the first facet mirror 20. Such tilting is initiated via the control unit 25 such that the actual value Z_{R} of the position of the center of gravity of the measured thermal load approximates or equals the center Z of the respective second facet 23. Such tilting of the micro mirrors 28 of the micro mirror group 29 may be done equally for all of the micro mirrors 28 of such micro mirror group 29, resulting in a respective shift of the actual value Z_{R} of the position of the center of gravity of the thermal load or, in particular when also taking into account further thermal load data, may be done individually for the micro mirrors 28 within the micro mirror group 29. In other words, with the readjustment, not only the position of the actual value Z_{R} of the center of gravity of the thermal load can be shifted, but also deviations of a contour and/or of a width of the source image 30 to given nominal values can be corrected.

Further, in particular with the thermal load sensors 34 of the micro mirrors 28 of the mirrors facets of the first facet mirror 20, a homogeneity of the thermal load and/or of the exposure via the illumination light 16 can be measured. These measurement data can be compared to independently obtained homogeneity data of the light source 3 indicating an inhomogeneity in the performance of the light source and/or an inhomogeneity of an absorbance of the individual micro mirrors 28 within the micro mirror group 29 constituting the respective mirror facet 21. In the same manner, also homogeneity measurements can be done with respect to the performance of the micro mirrors 28 of the second facet mirror 22. Such inhomogeneities then can be corrected via respective re-alignment of the light source and/or via refurbishment of the respective facet mirror 20 and/or 22.

A respective size or width adaption of the source image 30 may be done via a respective adaption of a curvature of the attributed mirror facet 21 of the first facet mirror 20. To this end, via the actuators 33, besides a tilt, also a bending and/or an adjustment perpendicular to the arrangement plane of the micro mirrors 28, i.e. along the z-direction, is possible.

A calibration of the respective mirror facets 21 of the first facet mirror 20, i.e. ensuring that all the individual micro mirrors 28 constituting a respective micro mirror 29 are at a correct relative position to each other to ensure correct generation of a source image 30 on the second facet mirror 22, can also be done in-line by using an area on the second facet mirror 22, which is not in use during projection exposure. In a variant of such in-line calibration, a respective single one of the mirror facets 21 of the first facet mirror 20 is actuated such that the respective micro mirror group 29 of the first facet mirror 20 images the light source onto an area of the second facet mirror 22 which is not in use for illumination conditioning. Drifts which might have occurred in the relative positioning between the micro mirrors 28 of such micro mirror group 29 to be calibrated can be recognized and compensated for during such in-line calibration.

Further, such readjustment method also is possible in case a correct attribution of the second facets 23 to the first mirror facets 21 has not yet taken place. In that case, in particular only one or selected ones of the mirror facets 21 of the first facet mirror 20 are illuminated with the illumination light 16, and it then is checked where the source images 30 generated by those mirror facets 21 occur on the second facet mirror 22. After the respective thermal load measurement and the identification of the respective source image 30, a readjustment via tilting and/or bending of the micro mirror group 29 constituting such mirror facet 21 of the first facet mirror 20 can be initiated to ensure the correct attribution.

Further, via the thermal load sensors 34 of all of the micro mirrors 28 of the second facet mirror 22, a given illumination pupil provided by the illuminated arrangement of the micro mirrors 28 on the second facet mirror 22 can be evaluated and compared to nominal values and, in case this is desired, corrected.

Further, different attribution schemes, which also are referred to as sorts, between the mirror facets 21 of the first facet mirror 20 and the second facets 23 of the second facet mirror 22 can be compared and evaluated. Such attribution comparison can be done fast due to the short thermal time-constant of the involved micro mirrors 28. Such illumination pupil evaluation can be done without the need to involve sensors related to the projection optics 10.

During the method, respectively determined actual values of positions Z_{R} of the centers of gravity of the thermal loads can be stored for each pair including the respective illuminated mirror facets 21 of the first facet mirror 20 and the attributed micro mirror group 27 of the second facet mirror 22. On these stored actual values, an analysis can be performed with the control unit 25 including further data, e.g. data from the light source 3, e.g. plasma alignment data in the case of a plasma source as the light source 3.

In particular, plasma misalignments can be detected.

During the projection exposure, the reticle 7 and the wafer 13, which bears a coating that is light-sensitive to the EUV illumination light 16, are provided. Subsequently, at least one portion of the reticle 7 is projected onto the wafer 13 with the aid of the projection exposure apparatus 1. Finally, the light-sensitive layer on the wafer 13 that has been exposed with the EUV illumination light 16 is developed. A microstructured or nanostructured component, for example a semiconductor chip, is produced in this way.

The exemplary embodiments described above were described on the basis of EUV illumination. As an alternative to EUV illumination, use can also be made of UV illumination or VUV illumination, for example illumination light with a wavelength of 193 nm.

What is claimed is:

1. A method of adjusting an illumination beam path within an illumination optics, the illumination optics comprising a first facet mirror comprising a plurality of mirror facets which are tiltable via respective actuators, and
a second facet mirror comprising a plurality of micro mirrors, each micromirror equipped with a thermal load sensor, the micro mirrors being groupable in micro mirror groups, each micro mirror group being attributed to one of the plurality of mirror facets of the first facet mirror via a given illumination channel within the illumination beam path, the method comprising:
a) guiding illumination light along a first raw illumination beam path via: at least one illuminated mirror facet of the field facet mirror; and the micro mirrors of the second facet mirror to which the illumination light is guided via the at least one illuminated mirror facet of the field facet mirror;
b) measuring a thermal load on the illuminated micro mirrors of the second facet mirror;
c) comparing the measured thermal load to nominal data; and
d) when a deviation between the measured thermal load and the nominal data is beyond a given tolerance, readjusting the illumination optics.

2. The method of claim 1, further comprising:
determining an actual value of a position of a center of gravity of the thermal load for a respective group of the illuminated micro mirrors of the second facet mirror using thermal load measurement data obtained during b);
comparing the actual value with a nominal value of the position of the center of gravity of the thermal load; and
when a distance between the actual value and the nominal value is beyond a given tolerance value for a given attributed micro mirror group, readjusting via the respective actuator the illuminated mirror facet of the field facet mirror until the distance is below the tolerance value.

3. The method of claim 2, further comprising:
guiding the illumination light along the first raw illumination beam path via: at least one illuminated mirror facet of the field facet mirror; and the attributed micro mirror group of the second facet mirror to which the illumination light is guided via the at least one illuminated mirror facet of the field facet mirror;
measuring the thermal load on the respectively attributed micro mirror groups;
determining, for each of the attributed micro mirror groups, an actual value of the position of the center of gravity of the thermal load;
comparing, for each of the attributed micro mirror groups, the actual value with a nominal value of the position of the center of gravity of the thermal load; and
when a distance between the actual value and the nominal value is beyond a given tolerance value for a given attributed micro mirror group, readjusting via the respective actuator the illuminated mirror facet of the field facet mirror to which the attributed micro mirror group belongs until such distance is below the tolerance value.

4. The method of claim 2, wherein b) occurs during production use of the illumination optics within a protection exposure apparatus.

5. The method of claim 1, wherein each mirror facet of the field facet mirror includes a plurality of micro mirrors each being equipped with a thermal load sensor, and wherein the method comprises measuring a thermal load on he illuminated micro mirrors of the first facet mirror.

6. The method of claim 5, further comprising:
guiding the illumination light along the first raw illumination beam path via: at least one illuminated mirror facet of the field facet mirror; and the attributed micro mirror group of the second facet mirror to which the illumination light is guided via the at least one illuminated mirror facet of the field facet mirror;
measuring the thermal load on the respectively attributed micro mirror groups;
determining, for each of the attributed micro mirror groups, an actual value of the position of the center of gravity of the thermal load;
comparing, for each of the attributed micro mirror groups, the actual value with a nominal value of the position of the center of gravity of the thermal load; and
when a distance between the actual value and the nominal value is beyond a given tolerance value for a given attributed micro mirror group, readjusting via the respective actuator the illuminated mirror facet of the field facet mirror to which the attributed micro mirror group belongs until such distance is below the tolerance value.

7. The method of claim 5, wherein b) occurs during production use of the illumination optics within a protection exposure apparatus.

8. The method of claim 1, further comprising:
guiding the illumination light along the first raw illumination beam path via: at least one illuminated mirror facet of the field facet mirror; and the attributed micro mirror group of the second facet mirror to which the illumination light is guided via the at least one illuminated mirror facet of the field facet mirror;
measuring the thermal load on the respectively attributed micro mirror groups;
determining, for each of the attributed micro mirror groups, an actual value of the position of the center of gravity of the thermal load;
comparing, for each of the attributed micro mirror groups, the actual value with a nominal value of the position of the center of gravity of the thermal load; and
when a distance between the actual value and the nominal value is beyond a given tolerance value for a given attributed micro mirror group, readjusting via the respective actuator the illuminated mirror facet of the field facet mirror to which the attributed micro mirror group belongs until such distance is below the tolerance value.

9. The method of claim 8, wherein b) occurs during production use of the illumination optics within a protection exposure apparatus.

10. The method of claim 8, wherein the attributed micro mirror group comprises a micro mirror array of at least 2×2 micro mirrors.

11. The method of claim 9, wherein guiding, measuring, and determining are performed for a plurality of illuminated mirror facets of the first facet mirror and respectively attributed micro mirror groups of the second facet mirror and the respectively determined actual values of the position of the center of gravity of the thermal load are stored for each pair comprising the respective illuminated mirror facets of the field facet mirror and the attributed micro mirror group of the second facet mirror.

12. The method of claim 1, wherein b) occurs during production use of the illumination optics within a protection exposure apparatus.

13. The method of claim 12, wherein groups of micro mirrors are used during b) which are not used for production use.

14. An illumination optics, comprising:
an adjustment system, comprising:
a first facet mirror comprising a plurality of mirror facets which are tiltable via respective actuators;
a second facet mirror comprising a plurality of micro mirrors, each micro mirror equipped with a thermal load sensor, the micro mirrors being groupable in micro mirror groups, each micro mirror group attributed to one of the plurality of mirror facets of the first facet mirror via a given illumination channel within an illumination beam path; and
a control unit in signal connection with the actuators of the mirror facets of the field facet mirror and with the thermal load sensors of the micro mirrors of the second facet mirror.

15. The illumination optics of claim 14, wherein each mirror facet of the field facet mirror comprises a plurality of micro mirrors, each micro mirror equipped with a thermal load sensor.

16. An illumination system, comprising:
an illumination light source; and
an illumination optics according to claim 14.

17. A projection exposure apparatus, comprising:
an illumination system, comprising:
an illumination light source; and
an illumination optics according to claim 14; and
a projection optical unit.

18. A method of using a projection exposure apparatus comprising an illumination optics unit and a projection optical unit, the method comprising:
using the illumination optics to at least partially illuminate an object in an object field of the projection optical unit; and
using the projection optical unit to image the illuminated portion of the object into an image field of the projection optical unit,
wherein the illumination optics unit comprises an illumination optics according to claim 14.

19. One or more machine-readable hardware storage devices comprising instructions that are executable by one or more processing devices to perform operations comprising the method of claim 1.

20. A system, comprising:
one or more processing devices; and
one or more machine-readable hardware storage devices comprising instructions that are executable by one or more processing devices to perform operations comprising the method of claim 1.
